(19) United States
(12) Patent Application Publication
(10) Pub. No.: US 2009/0173940 A1
(43) Pub. Date: Jul. 9, 2009

(54) Image Sensor and Method for Manufacturing the Same

(76) Inventor: Joon Hwang, Cheongju-si (KR)

Correspondence Address: SALIWANCHIK LLOYD & SALIWANCHIK;A PROFESSIONAL ASSOCIATION, PO Box 142950, GAINESVILLE, FL, 32614, US

(21) Appl. No.: 12/333,411

(22) Filed: Dec. 12, 2008

(30) Foreign Application Priority Data
Jan. 7, 2008 (KR) 10-2008-0001938

(51) Int. Cl. H01L 31/0376; H01L 21/20

(52) U.S. Cl. 257/53; 438/96; 257/E31.047; 257/E21.09

(57) ABSTRACT

An image sensor can include a first substrate, an amorphous layer, and a photodiode. A circuitry including a metal interconnection can be formed on the first substrate. The amorphous layer is disposed over the first substrate, and contacts the metal interconnection. The photodiode can be formed in a crystalline semiconductor layer and is bonded to the first substrate such that the photodiode contacts the amorphous layer and is electrically connected to the metal interconnection.

### CROSS-REFERENCE TO RELATED APPLICATION

The present application claims the benefit under 35 U.S.C. §119 of Korean Patent Application No. 10-2008-0001938, filed Jan. 7, 2008, which is hereby incorporated by reference in its entirety.

### BACKGROUND

An image sensor is a semiconductor device for converting an optical image into an electric signal. An image sensor can be generally classified as a charge coupled device (CCD) image sensor or a complementary metal oxide semiconductor (CMOS) image sensor (CIS).

A CIS includes a photodiode and a MOS transistor formed in a unit pixel, and obtains an image by sequentially detecting electrical signals of unit pixels in a switching manner.

In a related art CIS structure, a photodiode and a transistor are horizontally arranged.

Although the related art horizontal type CIS has solved certain limitations of CCD image sensors, it still has several problems.

In a horizontal type CIS according to the related art, a photodiode and a transistor are horizontally formed adjacent to each other on a substrate. Therefore, an additional region for forming the photodiode is required, which may decrease the fill factor and limit the possibility of resolution.

Also, in the horizontal type CIS according to the related art, it is very difficult to achieve the optimized process of concurrently forming the photodiode and the transistor. That is, a shallow junction is required to meet low sheet resistance in a rapid transistor process, but such a shallow junction may not be suitable for the photodiode.

Further, in the horizontal type CIS according to the related art, extra on-chip functions are added to the image sensor, and thus a unit pixel size should be increased to maintain the sensitivity of the image sensor, or an area for the photodiode should be decreased to maintain the pixel size. However, when the pixel size increases, the resolution of the image sensor decreases; and when an area of the photodiode decreases, the sensitivity of the image sensor becomes poor.

### BRIEF SUMMARY

Embodiments of the present invention relate to an image sensor and a manufacturing method thereof that provide a new integration of a circuitry and a photodiode.

Embodiments relate to an image sensor and a manufacturing method thereof that enhance resolution and sensitivity.

Embodiments relate to an image sensor and a manufacturing method thereof that employ a vertical type photodiode to enhance physical and electrical contact between the vertical type photodiode and a circuitry.

Embodiments relate to an image sensor and a manufacturing method thereof that employ a vertical type photodiode to reduce generation of a defect in the photodiode.

An image sensor according to an embodiment of the present invention can include: a first substrate on which a circuitry including a metal interconnection is formed; an amorphous layer over the first substrate, the amorphous layer contacting the metal interconnection; and a photodiode in a crystalline semiconductor layer and bonded to the first substrate, the photodiode contacting the amorphous layer and electrically connected to the metal interconnection.

A method for manufacturing an image sensor according to an embodiment of the present invention can include: preparing a first substrate on which a circuitry including a metal interconnection is formed; forming an amorphous layer over the first substrate, the amorphous layer contacting the metal interconnection; preparing a second substrate on which a photodiode is formed; bonding the first and second substrates to each other to contact the photodiode with the amorphous layer; and removing a portion of the bonded second substrate to expose the photodiode.

### BRIEF DESCRIPTION OF THE DRAWINGS

FIGS. 1 to 9 illustrate an image sensor and a method for manufacturing an image sensor in accordance with embodiments of the present invention.

### DETAILED DESCRIPTION

An image sensor and a method for manufacturing an image sensor in accordance with embodiments will be described in detail with reference to the accompanying drawings.

In the description of embodiments, it will be understood that when a layer (or film) is referred to as being ‘on’ another layer or substrate, it can be directly on another layer or substrate, or intervening layers may also be present. Further, it will be understood that when a layer is referred to as being ‘under’ another layer, it can be directly under another layer, or one or more intervening layers may also be present. In addition, it will also be understood that when a layer is referred to as being ‘between’ two layers, it can be the only layer between the two layers, or one or more intervening layers may also be present.

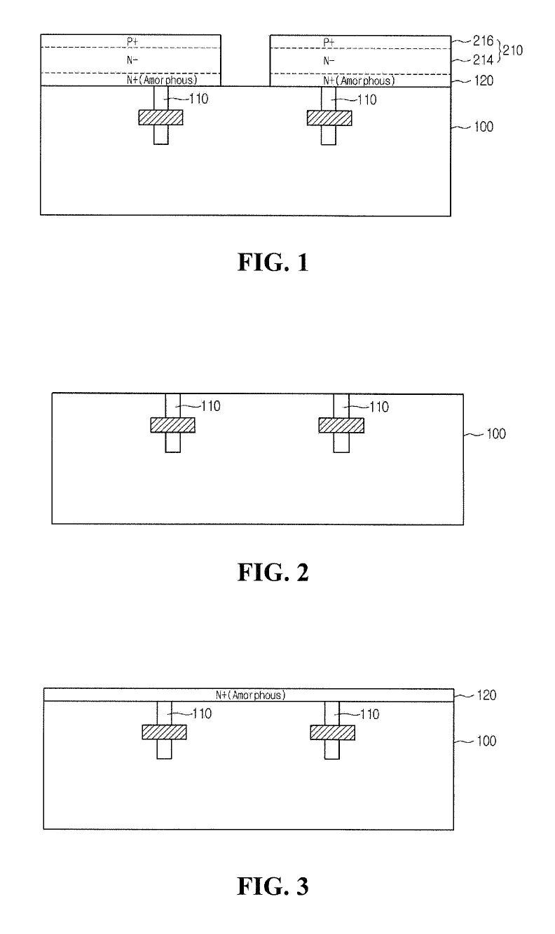

FIG. 1 shows a cross-sectional view of an image sensor in accordance with embodiments.

Referring to FIG. 1, an image sensor according to an embodiment can include: a first substrate 100 on which a circuitry (not shown) including a metal interconnection 110 is formed; an amorphous layer 120 disposed on the first substrate 100 and a photodiode 210 contacting the amorphous layer 120.

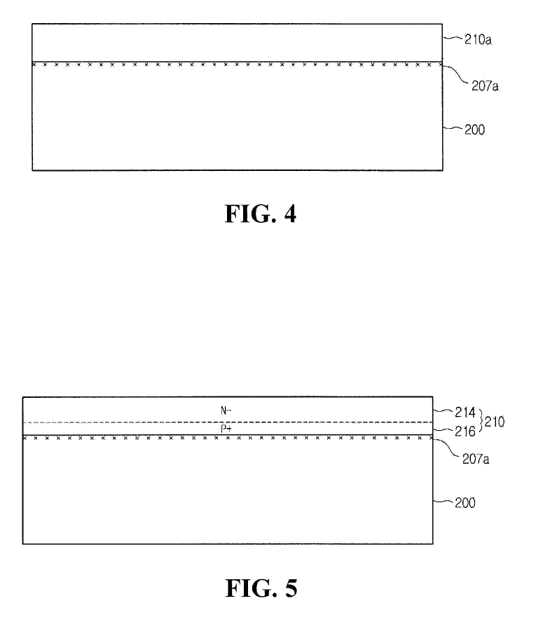

The amorphous layer 120 can contain the same element as the crystalline semiconductor layer 210a (see FIG. 4) in which the photodiode 210 is formed. Resultantly, since the image sensor in accordance with embodiments employs a vertical type photodiode, and includes the amorphous layer containing the same element as the photodiode between the photodiode and the circuitry, it is possible to improve physical and electrical contact between the photodiode and the circuitry.

For example, in the case where the element is silicon such that the crystalline semiconductor layer in which the photodiode is formed is made of crystalline silicon and the amorphous silicon layer is made of amorphous silicon, a bonding force between first and second substrates 100 and 200 can be increased by virtue of Si—Si bonding.

In a further embodiment, the amorphous layer 120 can include a high concentration first conduction type amorphous silicon layer. For example, the amorphous layer 120 can be heavily doped with N-type impurities so that it is possible to increase a contact force between the first substrate 100 and the second substrate 200 (see FIG. 4), and also achieve ohmic contact.

In certain embodiments, the amorphous layer 120 is formed to a thickness ranging from about 100 Å to about 1,000 Å so that the amorphous layer 120 can properly serve as a coupling layer and an ohmic contact layer between the first substrate 100 and the second substrate 200.

In embodiments, the crystalline semiconductor layer 210a can be but is not limited to a single crystalline semiconductor layer. For instance, the crystalline semiconductor layer 210a can be a polycrystalline semiconductor layer.

Although the circuitry of first substrate 100 is not shown, embodiments may be readily applied to 1 Tr CIS, 3 Tr CIS, 5 Tr CIS or 1.5 Tr CIS (i.e., transistor sharing CIS) configurations as well as a 4 Tr CIS configuration.

Also, the metal interconnection 110 on the first substrate 100 can include a plurality of metal layers and plugs. An uppermost portion of metal interconnection 110 can act as a lower electrode of the photodiode.

The photodiode 210 can include a first conduction type conduction layer 214 formed in a crystalline semiconductor layer 210a (see FIG. 4) and a second conduction type conduction layer 216 formed in the crystalline semiconductor layer 210a. For example, the photodiode 210 can include, but is not limited to, a low concentration N-type conduction layer 214 formed in the crystalline semiconductor layer 210a and a high concentration P-type conduction layer 216 formed in the crystalline semiconductor layer 210a. However, embodiments are not limited thereto. For example, the first conduction type may be P-type instead of N-type.

In further embodiments, a top metal (not shown) and a color filter may be further formed on the photodiode 210.

The photodiodes 210 can be separated for each pixel by a dielectric (not shown) disposed in the crystalline semiconductor layer and the amorphous layer at pixel boundaries.

FIGS. 2 through 9 illustrate a method for manufacturing an image sensor in accordance with embodiments.

Referring to FIG. 2, a first substrate 100 can be provided on which metal interconnection 110 and circuitry (not shown) are formed. The circuitry can be any suitable circuitry for a CIS. For example, the circuitry can be but is not limited to a 4 Tr CIS configuration.

The metal interconnection 110 can include a plurality of metal layers and plugs.

Referring to FIG. 3, an amorphous layer 120 can be formed on the first substrate 100, contacting the metal interconnection 110.

Here, the amorphous layer 120 can contain the same element as the crystalline semiconductor layer 210a (see FIG. 4) in which the photodiode 210 is formed. Resultantly, since the image sensor in accordance with embodiments employs a vertical type photodiode, and includes the amorphous layer containing the same element as the photodiode between the photodiode and the circuitry, it is possible to improve physical and electrical contact between the photodiode and the circuitry.

For example, in the case where the element is silicon such that the crystalline semiconductor layer in which the photodiode is formed is made of crystalline silicon and the amorphous silicon layer is made of amorphous silicon, a bonding force between first and second substrates 100 and 200 can be increased by virtue of the Si—Si bonding.

According to certain embodiments, a high concentration first conduction type amorphous layer can be formed in the amorphous layer 120 by implanting high concentration first conduction type impurity ions. For example, a high concentration N+ amorphous layer 120 can be formed by doping the amorphous layer 120 with high concentration N+ impurity ions. Consequently, a contact force between first substrate 100 and second substrate 200 is increased, and ohmic contact can be achieved as well.

In embodiments, the amorphous layer 120 can be formed to a thickness ranging from about 100 Å to about 1,000 Å so that the amorphous layer 120 can properly serve as a coupling layer and an ohmic contact layer between first substrate 100 and second substrate 200.

Referring to FIG. 4, a crystalline semiconductor layer 210a can be formed on a second substrate 200. Since a photodiode is formed in the crystalline semiconductor layer 210a, a defect inside the photodiode can be inhibited from occurring.

In an embodiment, the crystalline semiconductor layer 210a can be formed on the second substrate 200 by an epitaxial growth method. After that, hydrogen ions are implanted into an interface between the second substrate 200 and the crystalline semiconductor layer 210a to form a hydrogen ion implantation layer 207a.

Referring to FIG. 5, impurity ions can be implanted into crystalline semiconductor layer 210a to form the photodiode 210.

For example, a second conduction type conduction layer 216 can be formed in a lower portion of the crystalline semiconductor layer 210a.

For instance, the second conduction type conduction layer 216 can be a high concentration P-type conduction layer. The high concentration P-type conduction layer 216 can be formed in the lower portion of the crystalline semiconductor layer by performing a first blanket-ion implantation onto the entire surface of second substrate 200 without a mask. For instance, the second conduction type conduction layer 212 can be formed having a junction depth of less than about 0.5 μm.

After that, a first conduction type conduction layer 214 can be formed on the second conduction type conduction layer 216. Here, the first conduction type conduction layer 214 can be a low concentration N-type conduction layer. For example, the first conduction type conduction layer 214 can be formed on second conduction type conduction layer 216 by performing a second blanket-ion implantation onto the entire surface of second substrate 200 without a mask. The low concentration first conduction type conduction layer 214 can be formed at a junction depth ranging from about 1.0 μm to about 2.0 μm.

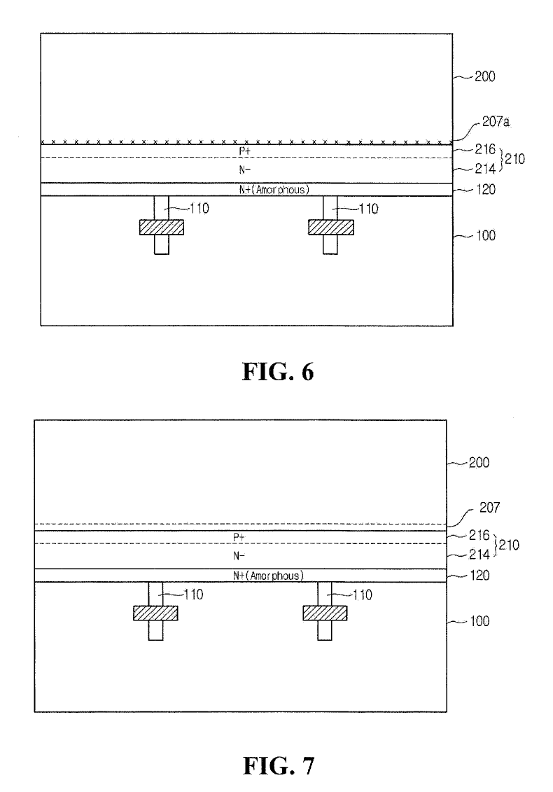

Next, referring to FIG. 6, the first substrate 100 and the second substrate 200 are bonded to each other such that photodiode 210 contacts the amorphous layer 120. For example, the bonding may be performed by contacting the first substrate 100 and the second substrate 200 with each other and then performing activation by plasma to increase a surface energy in a bonding surface.

Thereafter, referring to FIG. 7, the hydrogen ion implantation layer 207a can be changed into hydrogen gas layer 207 by performing a heat treatment on the second substrate 200.

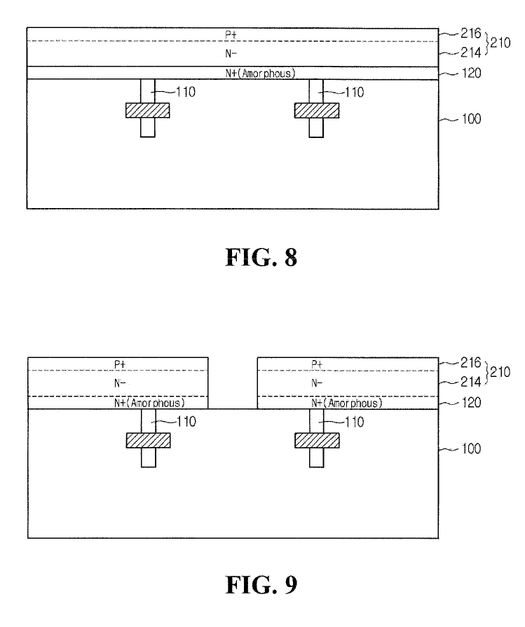

Afterwards, referring to FIG. 8, a portion of the second substrate 200 can then be removed with photodiode 210 left under the hydrogen gas layer so that photodiode 210 can be exposed.

Next, referring to FIG. 9 an etching process for separating the photodiode 210 for each unit pixel is performed. The etched portion can then be filled with a dielectric.

After that, processes for forming an upper electrode (not shown) and a color filter (not shown) may be performed.

The image sensor and method for manufacturing the same in accordance with embodiments can provide vertical integration of the circuitry and the photodiode.

Furthermore, the image sensor in accordance with embodiments employs a vertical type photodiode, and an amorphous layer containing the same element as the photodiode is inserted between the photodiode and a circuitry, thus making it possible to improve physical and electrical contact between the photodiode and the circuitry.

Moreover, in accordance with embodiments, since the image sensor employs a vertical type photodiode where the photodiode is positioned over a circuitry, and the photodiode is formed in the crystalline semiconductor layer, generation of a defect inside the photodiode can be reduced.

Although embodiments relate generally to a complementary metal oxide semiconductor (CMOS) image sensor, such embodiments are not limited to the same and may be readily applied to any image sensor requiring a photodiode.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An image sensor comprising:
a first substrate on which a circuitry including a metal interconnection is formed;
an amorphous layer over the first substrate, the amorphous layer contacting the metal interconnection; and
a photodiode in a crystalline semiconductor layer and bonded to the first substrate, the photodiode contacting the amorphous layer and electrically connected to the metal interconnection.

2. The image sensor of claim 1, wherein the amorphous layer comprises the same element as the crystalline semiconductor layer.

3. The image sensor of claim 2, wherein the element is silicon.

4. The image sensor of claim 2, wherein the amorphous layer comprises a first conduction type amorphous layer.

5. The image sensor of claim 4, wherein the amorphous layer has a thickness in a range of about 100 Å to about 1,000 Å.

6. The image sensor of claim 1, wherein the amorphous layer comprises a first conduction type amorphous layer.

7. The image sensor of claim 6, wherein the amorphous layer has a thickness in a range of about 100 Å to about 1,000 Å.

8. A method for manufacturing an image sensor, the method comprising:
preparing a first substrate on which a circuitry including a metal interconnection is formed;
forming an amorphous layer on the first substrate, the amorphous layer contacting the metal interconnection;
preparing a second substrate on which a photodiode is formed;
bonding the first and second substrates to each other to contact the photodiode with the amorphous layer; and
removing a portion of the bonded second substrate to expose the photodiode.

9. The method of claim 8, wherein the forming of the amorphous layer on the first substrate comprises forming an amorphous layer containing the same element as the crystalline semiconductor layer.

10. The method of claim 9, wherein the element is silicon.

11. The method of claim 10, wherein the forming of the amorphous layer over the first substrate comprises:
depositing an amorphous silicon layer on the first substrate; and
implanting first conduction type impurity ions into the amorphous silicon layer to form a first conduction type amorphous silicon layer.

12. The method of claim 11, wherein the depositing of the amorphous silicon layer on the first substrate comprises forming the amorphous silicon layer to a thickness in a range of about 100 Å to about 1,000 Å.

13. The method of claim 7, wherein the forming of the amorphous layer over the first substrate comprises:
depositing an amorphous layer on the first substrate; and
implanting first conduction type impurity ions into the amorphous layer to form a first conduction type amorphous layer.

14. The method of claim 9, wherein the depositing of the amorphous layer comprises forming the amorphous layer to a thickness in a range of about 100 Å to about 1,000 Å.
